(19) United States
(12) Patent Application Publication
(10) Pub. No.: US 2015/0074331 A1
(43) Pub. Date: Mar. 12, 2015

(54) NONVOLATILE MEMORY PACKAGE AND NONVOLATILE MEMORY CHIP

(71) Applicant: Kabushiki Kaisha Toshiba, Minato-ku (JP)

(72) Inventor: Keiichiro Endo, Shiki-shi (JP)

(73) Assignee: Kabushiki Kaisha Toshiba, Minato-ku (JP)

(21) Appl. No.: 14/193,148

(22) Filed: Feb. 28, 2014

Related U.S. Application Data
(60) Provisional application No. 61/875,811, filed on Sep. 10, 2013.

(51) Int. Cl. G11C 16/12; G11C 16/20

(52) U.S. Cl. CPC G11C 16/12; G11C 16/20
USPC 711/103

(57) ABSTRACT

A nonvolatile memory package of an embodiment includes: a data terminal configured to receive a write command for a data; a first CE terminal; a second CE terminal; a CE selection terminal; and a selector coupled to the first CE terminal and the second CE terminal. The selector outputs one of a first chip-enable signal and a second chip-enable signal based on a CE selection signal. The nonvolatile memory package of the embodiment further includes: a first nonvolatile memory chip that executes the write command for the data using the first chip-enable signal as an activate signal; and a second nonvolatile memory chip that changes an offset value for a write-destination address contained in the write command for the data based on the CE selection signal. The second nonvolatile memory chip executes the write command for the data using an output signal from the selector as an activate signal.

### CROSS-REFERENCE TO RELATED APPLICATIONS

This application is based upon and claims the benefit of priority from Provisional Patent Application No. 61/875,811, filed on Sep. 10, 2013; the entire contents of which are incorporated herein by reference.

### FIELD

Embodiments of the present invention relate to a nonvolatile memory package and a nonvolatile memory chip.

### BACKGROUND

In a controller for controlling a NAND flash memory, the number of Chip Enable (CE) terminals that can be coupled to the NAND flash memory is determined at a predetermined number. Similarly, with packages for NAND flash memories as well, the number of CE terminals is fixed at a predetermined number. A CE terminal is a terminal for the transmission/reception of Chip Enable (CE) signals for the controller to select a control-target NAND chip. The number of CE terminals in a controller is limited as described above. Therefore, if the capacity of a NAND flash memory coupled to the controller is to be changed, a package for a NAND flash memory of a different type matching the capacity of the on-board NAND flash memory is necessary.

For example, with a package in which the NAND flash memory mounted inside the package is four chips, as with two-CE-terminal and four-CE-terminal packages, developing a plurality of types is necessary so as to handle the capacity of the NAND flash memory onboard the controller. This increases the package development costs.

Likewise, in the case where a NAND flash memory is to be coupled to a controller whose number of CE terminals differs, this has necessitated the development of packages matching the number of CE terminals in the controller. This increases the package development costs.

### BRIEF DESCRIPTION OF THE DRAWINGS

FIG. 1 is a diagram illustrating a configuration of a nonvolatile memory package of a first embodiment of the present invention.

FIG. 2 is a diagram illustrating a configuration in which the nonvolatile memory package of the first embodiment of the present invention is coupled to a NAND controller.

FIG. 3 is a diagram illustrating a configuration in which two nonvolatile memory packages of the first embodiment of the present invention are coupled to a NAND controller.

FIG. 4 is a diagram illustrating a configuration of a nonvolatile memory package of a second embodiment of the present invention.

FIG. 5 is a diagram illustrating the configuration of a nonvolatile memory package of a third embodiment of the present invention.

FIG. 6 is a diagram illustrating another configuration of a nonvolatile memory package of the third embodiment of the present invention.

### DETAILED DESCRIPTION

A nonvolatile memory package in one embodiment of the present invention includes: a first data terminal configured to receive a write command for a first data; a first CE terminal configured to receive a first chip-enable signal; a second CE terminal configured to receive a second chip-enable signal; a CE selection terminal configured to receive a CE selection signal used to decide which the first chip-enable signal or the second chip-enable signal to be used; and a first selector coupled to the first CE terminal and the second CE terminal. The first selector outputs one of the first chip-enable signal and the second chip-enable signal based on the CE selection signal. A nonvolatile memory package of the embodiment further includes: a first nonvolatile memory chip and a second nonvolatile memory chip. The first nonvolatile memory chip is coupled to the first data terminal and the first CE terminal. The first nonvolatile memory chip executes the write command for the first data using the first chip-enable signal as an activate signal. The second nonvolatile memory chip is coupled to the first data terminal, the first selector, and the CE selection terminal. The second nonvolatile memory chip changes an offset value for a write-destination address contained in the write command for the first data based on the CE selection signal. The second nonvolatile memory chip executes the write command for the first data using an output signal from the first selector as an activate signal.

Below, referring to the attached drawings, an explanation of nonvolatile memory packages and nonvolatile memory chips according to embodiments will be made in detail. It should be understood that the present invention is not limited to these embodiments.

### First Embodiment

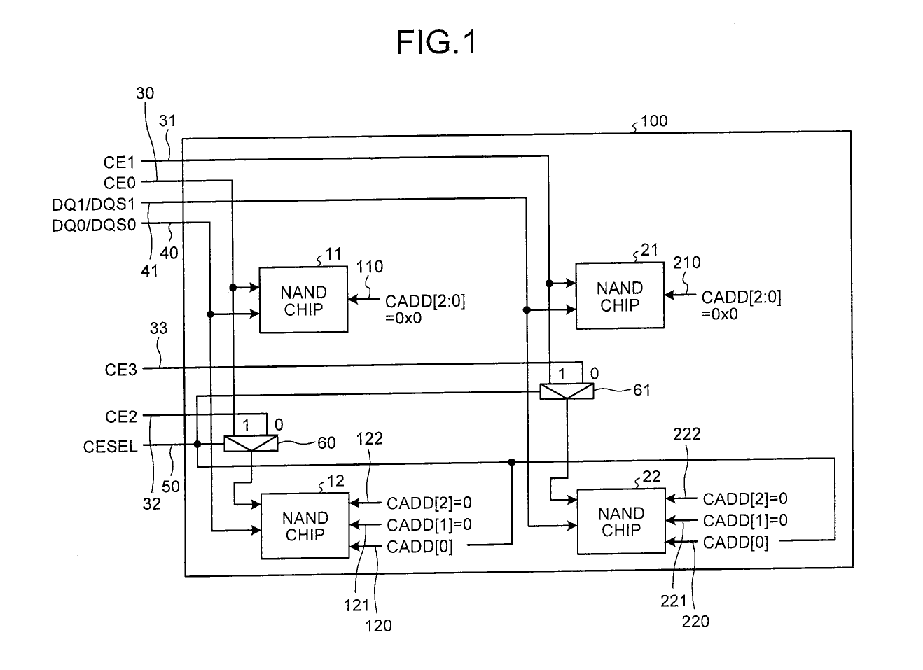

FIG. 1 is a diagram illustrating a configuration of a nonvolatile memory package 100 in an embodiment of the present invention. The nonvolatile memory package 100 includes NAND chips 11, 12, 21 and 22, and selectors 60 and 61. The nonvolatile memory package 100 further includes: CE terminals 30 to 33 that receive CE signals indicative of that writing of data into the NAND chips is possible, from a NAND controller; a data terminal 40 (DQ0/DQS0) and a data terminal 41 (DQ1/DQS1) that receive write data and its address information (write addresses), from the NAND controller; and a CE selection terminal 50 (CESEL) that receives a CE selection signal causing the selectors 60 and 61 to select a CE signal from the CE terminals.

The data terminal 40 is coupled to the NAND chip 11 (first chip) and the NAND chip 12 (second chip). The CE terminal 30 (CE0), which receives a first chip-enable signal, is coupled to the NAND chip 11 and the selector 60. The CE terminal 32 (CE2), which receives a second chip-enable signal, is coupled to the selector 60. Output from the selector 60 is input as a CE signal to the NAND chip 12. The selector 60 is switched by the CE selection terminal 50.

The data terminal 41 is coupled to the NAND chip 21 (third chip) and the NAND chip 22 (fourth chip). The CE terminal 31 (CE1), which receives a third chip-enable signal, is coupled to the NAND chip 21 and the selector 61. The CE terminal 33 (CE3), which receives a fourth chip-enable signal, is coupled to the selector 61. Output from the selector 61 is input as a CE signal to the NAND chip 22. The selector 61 is switched by the CE selection terminal 50.

As for the selector 60, when the value of the CE selection signal input through the CE selection terminal 50 is “1,” the selector 60 inputs the CE signal that the CE terminal 30 has received to the NAND chip 12, and when the value of the CE selection signal is “0,” the selector 60 inputs the CE signal that the CE terminal 32 has received to the NAND chip 12. As for the selector 61, when the value of the CE selection signal is “1,” the selector 61 inputs the CE signal that the CE terminal 31 has received to the NAND chip 22, and when the value of the CE selection signal is “0,” the selector 61 inputs the CE signal that the CE terminal 33 has received to the NAND chip 22.

The NAND chip includes an address decoder that recognizes whether address information involving write data from the NAND controller, received through the data terminals (DQ/DQS), is its own address. Then, the NAND chip includes address-offset switching terminals as terminals through which offsets (address offsets) for the received address information are switched. In FIG. 1, the NAND chip 11 includes an address-offset switching terminal 110, the NAND chip 12 includes address-offset switching terminals 120 to 122, the NAND chip 21 includes an address-offset switching terminal 210, and the NAND chip 22 includes address-offset switching terminals 220 to 222. To the address-offset switching terminals 110 and 210, “0x0,” which is a hexadecimal 3-bit CADD [2:0] value, (with “0x” indicating hexadecimal notation) is input. To the address-offset switching terminals 120 and 220, a value for the CE selection terminal is input as the value CADD [0] (bit 0 in CADD [2:0]). To the address-offset switching terminals 121 and 221, “0” is input as the value CADD [1] (bit 1 in CADD [2:0]). To the address-offset switching terminals 122 and 222, “0” is input as the value CADD [2] (bit 2 in CADD [2:0]).

To the address-offset switching terminals 110 and 210 together, “0x0,” which is a fixed value, is input. However, the input value to the address-offset switching terminals for the NAND chip 12 and the NAND chip 22 is switchable by the CE selection terminal 50. Specifically, 3-bit values are expressed through the address-offset switching terminals 120 to 122. The fixed value “0” is input to the address-offset switching terminals 121 and 122 together, which represent the two upper-place digits (bit 1 and bit 2). However, the CE selection terminal 50 is coupled to the address-offset switching terminal 120, which represents the lowest-place bit (bit 0). Similarly, the fixed value “0” is input to the address-offset switching terminals 221 and 222 together. However, the he CE selection terminal 50 is coupled to the address-offset switching terminal 220, which represents the lowest-place bit.

When the value of the CE selection signal is “0,” the CE signal that the CE terminal 32 has received is input to the NAND chip 12. Data received through the data terminals can be written into the NAND chip which has received the CE signal in the period in which the CE signal is being asserted. Accordingly, the NAND chip 11 and the NAND chip 12, which are together coupled to the data terminal 40, are exclusively writable with data from the data terminal 40 by the CE signal input to the NAND chip 11 through the CE terminal 30 (first chip-enable signal), and the CE signal input to the NAND chip 12 through the CE terminal 32 (second chip-enable signal). In that case, the “0” is input also to the address-offset switching terminal 120 that represents the lowest-place bit in the address offset for the NAND chip 12, making the address offset the same “0x0” as for the NAND chip 11. Nevertheless, since different CE signals are input to the NAND chips 11 and 12, it is possible to select the chip in the writing. That is, the NAND chips 11 and 12 within the same channel, together coupled to the data terminal 40, can be, by different CE signals, bank-interleaved and written into separately. This is likewise the case with the NAND chips 21 and 22, together coupled to the data terminal 41.

When the value of the CE selection signal is “1,” the same CE signal that the CE terminal 30 has received is input both to the NAND chip 11 and the NAND chip 12, together coupled to the data terminal 40. However, the input value to the address-offset switching terminal 120 for the NAND chip 12 is switchable by the CE selection terminal 50. This makes it possible to write the write data from the data terminal 40, correctly in accordance with the address, into the NAND chip 11 and the NAND chip 12. The reason is that the fixed value “0x0” is input to the NAND chip 11 through the address-offset switching terminal 110 while “1,” which is the value of the CE selection signal, is input to the NAND chip 12 through the address-offset switching terminal 120 to use the address-offset value “0x1” so as to assign an address offset to the write data from the data terminal 40. It is because even with the same CE signal being input to the NAND chips 11 and 12, whether the data information from the data terminal 40 is write data for the NAND chip 11 or write data for the NAND chip 12 can be exclusionarily discriminated via the address offset. Specifically, while each chip determines an address range of predetermined value (address decode range) from a start address as a range of data that is to be written into itself, if an address offset is assigned to it, the chip determines by assigning the offset for a predetermined amount of address quantity, for example, the amount of the above-described address-decode range, to the start address. This is likewise the case with the NAND chips 21 and 22, together coupled to the data terminal 41.

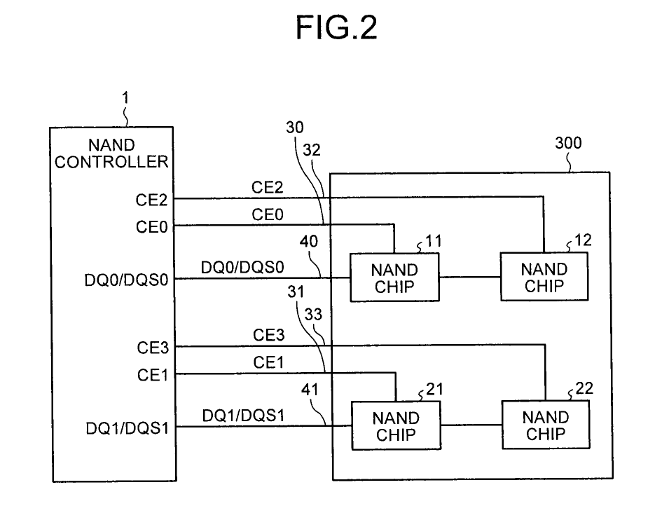

By the above-described function of the nonvolatile memory package 100, it is possible, when the value of the CE selection signal is “0,” for the nonvolatile memory package 100 to take on the configuration of a nonvolatile memory package 300 in FIG. 2 and be coupled to a NAND controller 1. As illustrated in FIG. 2, the NAND controller 1 has four CE terminals and two data terminals. Accordingly, the nonvolatile memory package 100 is also put into the configuration of the nonvolatile memory package 300, which includes four CE terminals and two data terminals, corresponding to the NAND controller 1.

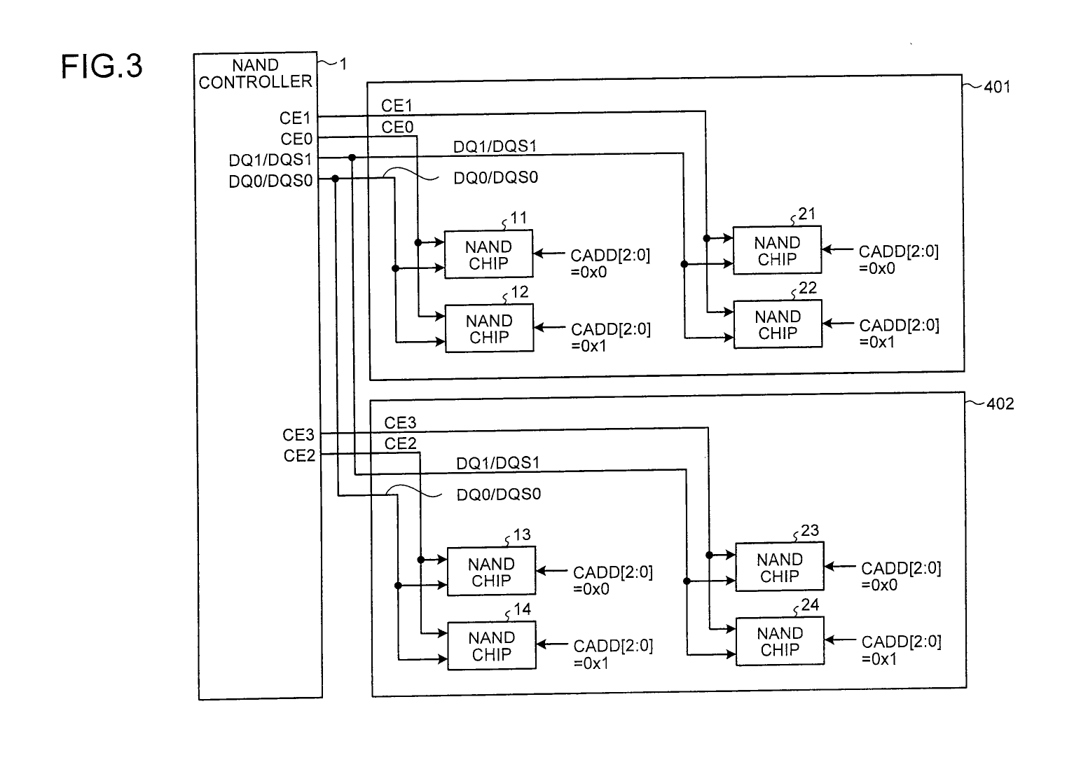

When the value of the CE selection signal is “1,” the nonvolatile memory package 100 takes on the configuration of a nonvolatile memory package 401 of FIG. 3 and can be coupled to the NAND controller 1. In situations where the value of the CE selection signal is “1,” a configuration is adopted in which as described above, the NAND chips 11 and 12 in FIG. 1 are coupled to the CE terminal 30 (CE0), and the NAND chips 21 and 22 are coupled to the CE terminal 31 (CE1). Accordingly, if the nonvolatile memory package 100 thus configured is coupled to the two CE terminals (CE0 and CE1) and the two data terminals (DQ0/DQS0 and DQ1/DQS1) of the NAND controller 1 of FIG. 3, the nonvolatile memory package 100 functions as the nonvolatile memory package 401. The nonvolatile memory package 401 is put into a configuration having the two CE terminals and the two data terminals.

Then, by preparing one more additional nonvolatile memory package 100 for which the value of the CE selection signal is “1,” and coupling it to the remaining two terminals (CE2 and CE3) and two data terminals (DQ0/DQS0 and DQ1/DQS1) of the NAND controller 1 of FIG. 3, it is made to function as a nonvolatile memory package 402. That is, by coupling the two nonvolatile memory packages 100 with CE selection signal values of “1” to the NAND controller 1 of FIG. 3, they are made to function as the nonvolatile memory packages 401 and 402. This makes it possible to double the capacity of the NAND flash memory, coupled to the NAND controller 1, in FIG. 3 compared with FIG. 2.

Preparing two nonvolatile memory packages that have the configuration of the nonvolatile memory package 300 illustrated in FIG. 2 and coupling them to the NAND controller 1 as illustrated in FIG. 3 to double the capacity would be impossible, in that it would mean being compelled to couple identical CE terminals to a plurality of NAND chips coupled to identical data terminals. That is, in an instance where the nonvolatile memory package 100 according to the present embodiment is not adopted, if the nonvolatile memory packages 401 and 402 that are different from the configuration of the nonvolatile memory package 300 were not made available, then increasing the capacity of the nonvolatile memory that can be coupled to the NAND controller 1 would have been impossible. However, with the nonvolatile memory package 100 according to the present embodiment, switching the value of the CE selection signal input through the CE selection terminal 50 makes it possible to put the package into the configuration represented in FIG. 2 or FIG. 3. This allows readily changing the capacity of the nonvolatile memory that can be coupled to the NAND controller 1.

According to the first embodiment, in the nonvolatile memory package, a selector that switches signals from the CE terminal is provided, and the address-offset value in the address decode for the chip coupled to the selector is changed based on selection by the selector. This allows facilitating enlargement of the capacity of the NAND flash memory coupled to a controller whose number of CE terminals that can be coupled is fixed. Accordingly, the types of package that are developed can be reduced, allowing a decrease in development costs.

### Second Embodiment

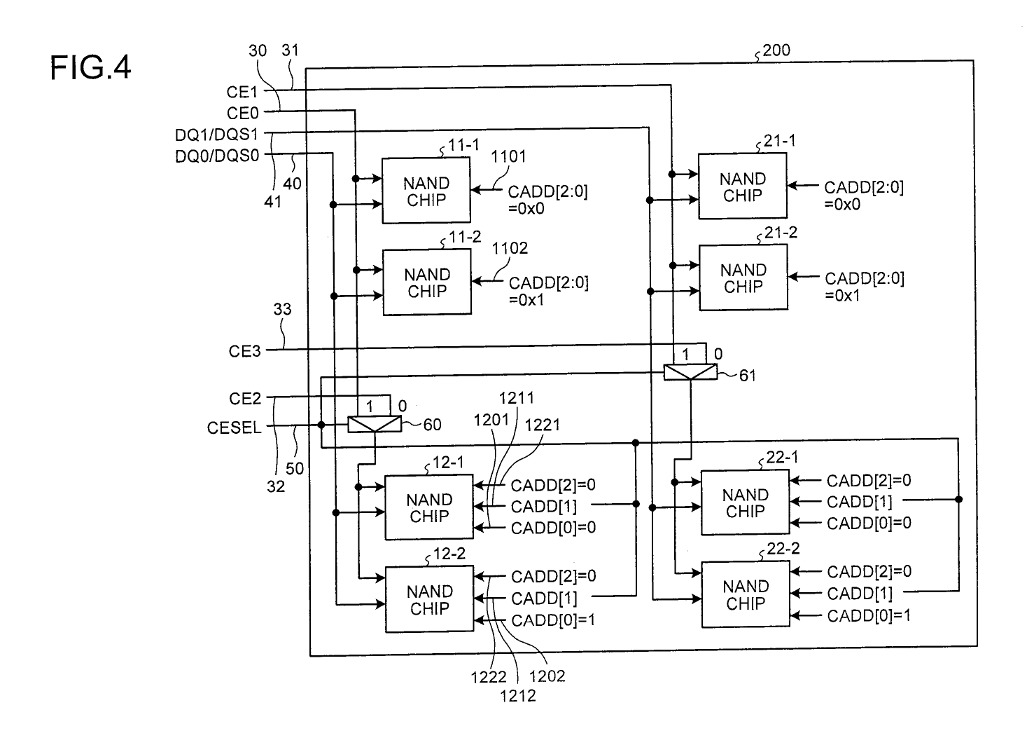

To realize the above-described functionality of the nonvolatile memory package 100 illustrated in FIG. 1: it is realizable as a configuration that is half that, with the NAND chips 11 and 12 and the selector 60 being a minimal configuration. With this minimal configuration, it is possible to switch between a configuration having two CE terminals and one data terminal, and a configuration having one CE terminal and one data terminal. Nevertheless, conversely, the capacity of the NAND flash memory of FIG. 1 may be doubled to configure a nonvolatile memory package 200 as illustrated in FIG. 4. The nonvolatile memory package 200 includes NAND chips 11-1 (first chip), 11-2 (fifth chip), 12-1 (second chip), 12-2 (sixth chip), 21-1 (third chip), 21-2 (seventh chip), 22-1 (fourth chip), and 22-2 (eighth chip), and the selectors 60 and 61. The nonvolatile memory package 200 further includes the CE terminals 30 to 33, the data terminal 40 (DQ0/DQS0), the data terminal 41 (DQ1/DQS1), and the CE selection terminal 50 (CESEL).

The data terminal 40 is coupled to the NAND chips 11-1, 11-2, 12-1 and 12-2. The CE terminal 30 (CE0) is coupled to the NAND chips 11-1 and 11-2, and the selector 60. The CE terminal 32 (CE2) is coupled to the selector 60. The output of the selector 60 is input to the NAND chips 12-1 and 12-2 as a CE signal. The selector 60 is switched by the CE selection terminal 50. The relationships among the NAND chips 21-1, 21-2, 22-1 and 22-2 coupled to the data terminal 41, the selector 61, the CE terminal 31 (CE1), the CE terminal 33 (CE3), and the CE selection terminal 50 are in the same manner.

As for the selector 60, when the value of the CE selection signal is “1,” the selector 60 inputs the CE signal that the CE terminal 30 has received to the NAND chips 12-1 and 12-2, and when the value of the CE selection signal is “0,” the selector 60 inputs the CE signal that the CE terminal 32 has received to the NAND chips 12-1 and 12-2. As for the selector 61, when the value of the CE selection signal is “1,” the selector 61 inputs the CE signal that the CE terminal 31 has received to the NAND chips 22-1 and 22-2, and when the value of the CE selection signal is “0,” the selector 61 inputs the CE signal that the CE terminal 33 has received to the NAND chips 22-1 and 22-2.

The NAND chip 11-1 includes an address-offset switching terminal 1101, the NAND chip 11-2 includes an address-offset switching terminal 1102, the NAND chip 12-1 includes address-offset switching terminals 1201, 1211, and 1221, and the NAND chip 12-2 includes address-offset switching terminals 1202, 1212, and 1222.

To the address-offset switching terminal 1101, “0x0,” which is a fixed value, is input. To the address-offset switching terminal 1102, “0x1,” which is a fixed value, is input. However, the input values to the address-offset switching terminals for the NAND chip 12-1 and the NAND chip 12-2 are switchable by the CE selection terminal 50. A 3-bit value is created by the address-offset switching terminals 1201, 1211, and 1221, and a 3-bit value is created by the address-offset switching terminals 1202, 1212, and 1222, but the address-offset switching terminals 1211 and 1212 that are the digit in the middle (bit 1) are switchable by the CE selection terminal 50. The fixed value “0” is input to the address-offset switching terminals 1221 and 1222 together, which represent the highest-place digit (bit 2); the fixed value “0” is input to the address-offset switching terminal 1201, which represents the lowest-place digit (bit 0); and the fixed value “1” is input to the address-offset switching terminal 1202, which represents the lowest-place digit (bit 0). The configuration of the address-offset switching terminals for the NAND chips 21-1, 21-2, 22-1, and 22-2 are in the same manner.

When the value of the CE selection signal is “0,” the CE signal that the CE terminal 32 has received is input to the NAND chips 12-1 and 12-2. Accordingly, exclusively writing the NAND chips 11-1 and 11-12 and the NAND chips 12-1 and 12-2, which are together coupled to the data terminal 40, with data from the data terminal 40 is possible, by the CE signal (first chip-enable signal) input to the NAND chips 11-1 and 11-2 through the CE terminal 30, and the CE signal (second chip-enable signal) input to the NAND chips 12-1 and 12-2 through the CE terminal 32. The NAND chips 11-1 and 11-2 are together input with the CE signal from the CE terminal 30, but as explained above, to the address-offset switching terminal 1101, “0x0” is input, while to the address-offset switching terminal 1102, an offset value that differs from “0x1” is input, such that writing exclusively regardless of the value of the CE selection signal is possible. When the value of the CE selection signal is “0,” “0” is also input to the address-offset switching terminals 1211 and 1212, which represent the bit at the middle of the address offsets for the NAND chips 12-1 and 12-2, making the address offset for the NAND chip 12-1 the same “0x0” as for the NAND chip 11-1, and making the address offset for the NAND chip 12-2 the same “0x1” as for the NAND chip 11-2. Nevertheless, since a CE signal input to the NAND chips 11-1 and 11-2 is different from a CE signal input to the NAND chips 12-1 and 12-2, it is possible to select the chip in the writing. That is, the NAND chips 11-1, 11-2, 12-1, and 12-2 within the same channel, together coupled to the data terminal 40, can be bank-interleaved and written into separately by one same CE signal for the NAND chips 11-1 and 11-2, and another same CE signal for the NAND chips 12-1 and 12-2. This is likewise the case with the NAND chips 21-1, 21-2, 22-1, and 22-2, together coupled to the data terminal 41.

When the value of the CE selection signal is “1,” the same CE signal that the CE terminal 30 has received is input both to the NAND chips 11-1 and 11-2 and the NAND chips 12-1 and 12-2, together coupled to the data terminal 40. However, the input values to the address-offset switching terminals 1211 and 1212 for the NAND chips 12-1 and 12-2 are switchable by the CE selection terminal 50. This makes it possible to sort and write the write data from the data terminal 40, correctly in accordance with the addresses, into the NAND chips 11-1, 11-2, 12-1, and 12-2. The reason is that the fixed value “0x0” is input to the NAND chip 11-1 through the address-offset switching terminal 1101, the fixed value “0x1” is input to the NAND chip 11-2 through the address-offset switching terminal 1102, “1,” which is the value of the CE selection signal, is input to the address-offset switching terminal 1211 for the NAND chip 12-1 to use the address-offset value “0x2” so as to assign an address offset to the write data, and “1,” which is the value of the CE selection signal, input to the address-offset switching terminal 1212 for the NAND chip 12-2 to use the address-offset value “0x3” so as to assign an address offset to the write data. It is because even with the same CE signal being input to the NAND chips 11-1, 11-2, 12-1, and 12-2, whether the data information from the data terminal 40 is write data for the NAND chip 11-1, 11-2, 12-1, or 12-2 can be exclusionarily discriminated. This is likewise the case with the NAND chips 21-1, 21-2, 22-1 and 22-2, together coupled to the data terminal 41.

The above-described function of the nonvolatile memory package 200 makes it possible to realize the configurations illustrated in FIGS. 2 and 3, which are realizable utilizing the nonvolatile memory package 100, each at two times the NAND flash-memory capacity. Further, practical applications of the present embodiment configuration makes possible, by putting the input destination through the CE selection terminal 50 at a further upper-place digit in the address offset, multiplying the NAND flash-memory capacity another two times or four times.

According to the second embodiment, the number of nonvolatile memory package chips of the first embodiment is enlarged, and meanwhile the digits in the address-offset value that is changed based on selection by the selectors are varied. This further facilitates changing the capacity of a NAND flash memory onboard a controller whose CE terminal count that can be coupled is fixed.

### Third Embodiment

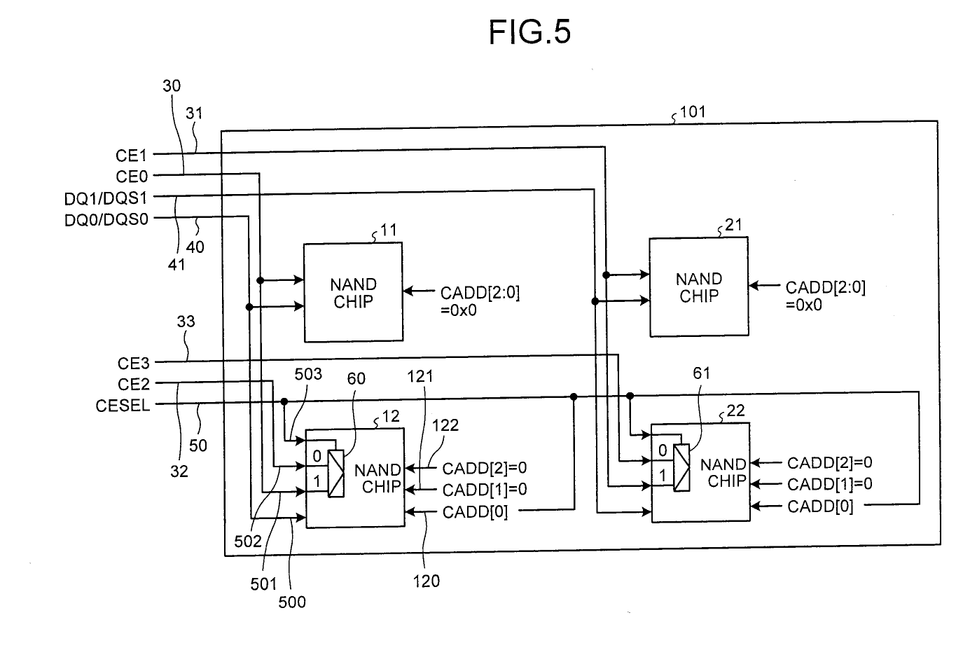

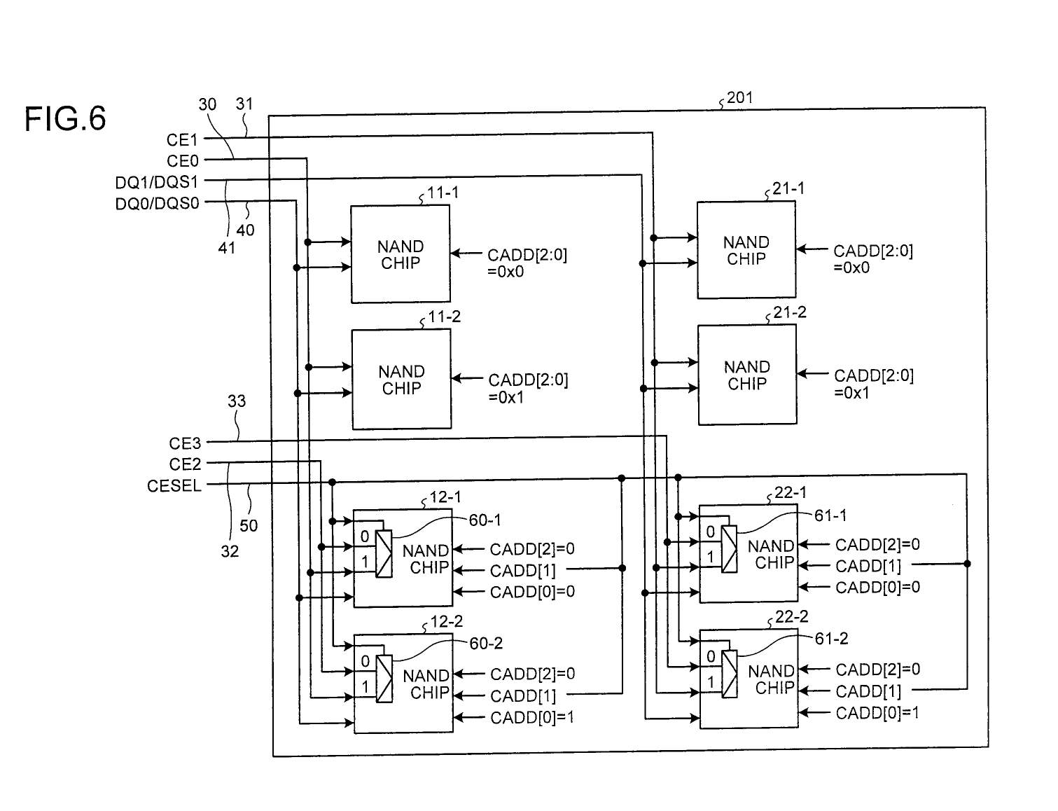

While in the nonvolatile memory package 100 of FIG. 1 and the nonvolatile memory package 200 of FIG. 4, the selectors 60 and 61 are provided inside the packages separately from the NAND chips, the selectors 60 and 61 may be built into the NAND chips. A nonvolatile memory package 101 of FIG. 5 is a configuration in which the selectors 60 and 61 are built respectively into the NAND chips 12 and 22 of FIG. 1. A nonvolatile memory package 201 of FIG. 6 is a configuration in which selectors 60-1 and 60-2, with the same functionality as the selector 60, are built into the NAND chips 12-1 and 12-2 of FIG. 4, and in which selectors 61-1 and 61-2, with the same functionality as the selector 61, are built into the NAND chips 22-1 and 22-2.

An explanation will be made taking the NAND chip 12 of FIG. 5 as an example. The NAND chip 12 includes: a data terminal 500 that receives write data and its address information (write addresses) through the data terminal 40 (DQ0/DQS0) of the nonvolatile memory package 101; a CE terminal 501 that receives a chip-enable signal through the CE terminal 30; a CE terminal 502 that receives a chip-enable signal through the CE terminal 32; a CE selection terminal 503 that receives a CE selection signal through the CE selection terminal 50; and the selector 60 that switches the signals from the CE terminal 502, the address-offset switching terminals 120 to 122, and the CE selection terminal 503, based on the CE selection signal. The address-offset switching terminal 120 also receives the CE selection signal through the CE selection terminal 50. Then, the offset value for the write address of the data that the data terminal 500 has received is changed based on the CE selection signal received through the address-offset switching terminal 120.

According to the third embodiment, the selectors of the first and second embodiments are built into the chips. This ensures the simplified configurations of the nonvolatile memory package.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory package, comprising:
a first data terminal configured to receive a write command for a first data;
a first CE terminal configured to receive a first chip-enable signal;
a second CE terminal configured to receive a second chip-enable signal;
a CE selection terminal configured to receive a CE selection signal used to decide which the first chip-enable signal or the second chip-enable signal to be used;
a first selector coupled to the first CE terminal and the second CE terminal, the first selector outputting one of the first chip-enable signal and the second chip-enable signal based on the CE selection signal;
a first nonvolatile memory chip coupled to the first data terminal and the first CE terminal, the first nonvolatile memory chip executing the write command for the first data using the first chip-enable signal as an activate signal; and
a second nonvolatile memory chip coupled to the first data terminal, the first selector, and the CE selection terminal, the second nonvolatile memory chip changing an offset value for a write-destination address contained in the write command for the first data based on the CE selection signal, the second nonvolatile memory chip executing the write command for the first data using an output signal from the first selector as an activate signal.

2. The nonvolatile memory package according to claim 1, wherein
the second nonvolatile memory chip is configured:
to set the offset value for the write-destination address contained in the write command for the first data when the first selector outputs the first chip-enable signal based on the CE selection signal; and
not to set the offset value for the write-destination address contained in the write command for the first data when the first selector outputs the second chip-enable signal based on the CE selection signal.

3. The nonvolatile memory package according to claim 1, wherein
the second nonvolatile memory chip switches any of digits of the offset value for the write-destination address contained in the write command for the first data based on the CE selection signal.

4. The nonvolatile memory package according to claim 1, wherein
the first selector outputs the first chip-enable signal when the CE selection signal is 1, and outputs the second chip-enable signal when the CE selection signal is 0; and
the second nonvolatile memory chip adds value according to the CE selection signal to the offset value for the write-destination address contained in the write command for the first data.

5. The nonvolatile memory package according to claim 1, further comprising:
a second data terminal configured to receive a write command for a second data;
a third CE terminal configured to receive a third chip-enable signal;
a fourth CE terminal configured to receive a fourth chip-enable signal;
a second selector coupled to the third CE terminal and the fourth CE terminal, the second selector outputting one of the third chip-enable signal and the fourth chip-enable signal based on the CE selection signal;
a third nonvolatile memory chip coupled to the second data terminal and the third CE terminal, the third nonvolatile memory chip executing the write command for the second data using the third chip-enable signal as an activate signal; and
a fourth nonvolatile memory chip coupled to the second data terminal, the second selector, and the CE selection terminal, the fourth nonvolatile memory chip changing an offset value for a write-destination address contained in the write command for the second data based on the CE selection signal, the fourth nonvolatile memory chip executing the write command for the second data using an output signal from the second selector as an activate signal.

6. The nonvolatile memory package according to claim 5, wherein
the fourth nonvolatile memory chip is configured:
to set the offset value for the write-destination address contained in the write command for the second data when the second selector outputs the third chip-enable signal based on the CE selection signal; and
not to set the offset value for the write-destination address contained in the write command for the second data when the second selector outputs the fourth chip-enable signal based on the CE selection signal.

7. The nonvolatile memory package according to claim 5, wherein
the fourth nonvolatile memory chip switches any of digits of the offset value for the write-destination address contained in the write command for the second data based on the CE selection signal.

8. The nonvolatile memory package according to claim 5, wherein
the second selector outputs the third chip-enable signal when the CE selection signal is 1, and outputs the fourth chip-enable signal when the CE selection signal is 0; and
the fourth nonvolatile memory chip adds value according to the CE selection signal to the offset value for the write-destination address contained in the write command for the second data.

9. The nonvolatile memory package according to claim 1, further comprising:
a fifth nonvolatile memory chip coupled to the first data terminal and the first CE terminal, the fifth nonvolatile memory chip setting a fixed offset value for the write-destination address contained in the write command for the first data, the fifth nonvolatile memory chip executing the write command for the first data using the first chip-enable signal as an activate signal; and
a sixth nonvolatile memory chip coupled to the first data terminal, the first selector, and the CE selection terminal, the sixth nonvolatile memory chip changing an adding offset value which is added to the fixed offset value for the write-destination address contained in the write command for the first data based on the CE selection signal, the sixth nonvolatile memory chip executing the write command for the first data using an output signal from the first selector as an activate signal.

10. The nonvolatile memory package according to claim 9, wherein
the sixth nonvolatile memory chip is configured:
to set the adding offset value for the write-destination address contained in the write command for the first data when the first selector outputs the first chip-enable signal based on the CE selection signal; and
not to set the adding offset value for the write-destination address contained in the write command for the first data when the first selector outputs the second chip-enable signal based on the CE selection signal.

11. The nonvolatile memory package according to claim 9, wherein
the sixth nonvolatile memory chip switches any of digits of the offset value for the write-destination address contained in the write command for the first data based on the CE selection signal.

12. The nonvolatile memory package according to claim 9, wherein
the first selector outputs the first chip-enable signal when the CE selection signal is 1, and outputs the second chip-enable signal when the CE selection signal is 0; and
the sixth nonvolatile memory chip adds value according to the CE selection signal to the offset value for the write-destination address contained in the write command for the first data.

13. The nonvolatile memory package according to claim 5, further comprising:
a fifth nonvolatile memory chip coupled to the first data terminal and the first CE terminal, the fifth nonvolatile memory chip setting a fixed offset value for the write-destination address contained in the write command for the first data, the fifth nonvolatile memory chip executing the write command for the first data using the first chip-enable signal as an activate signal; and
a sixth nonvolatile memory chip coupled to the first data terminal, the first selector, and the CE selection terminal, the sixth nonvolatile memory chip changing an adding offset value which is added to the fixed offset value for the write-destination address contained in the write command for the first data based on the CE selection signal, the sixth nonvolatile memory chip executing the write command for the first data using an output signal from the first selector as an activate signal.

14. The nonvolatile memory package according to claim 13, wherein
the sixth nonvolatile memory chip is configured:
to set the adding offset value for the write-destination address contained in the write command for the first data when the first selector outputs the first chip-enable signal based on the CE selection signal; and
not to set the adding offset value for the write-destination address contained in the write command for the first data when the first selector outputs the second chip-enable signal based on the CE selection signal.

15. The nonvolatile memory package according to claim 13, wherein
the sixth nonvolatile memory chip switches any of digits of the offset value for the write-destination address contained in the write command for the first data based on the CE selection signal.

16. The nonvolatile memory package according to claim 13, wherein
the first selector outputs the first chip-enable signal when the CE selection signal is 1, and outputs the second chip-enable signal when the CE selection signal is 0; and
the sixth nonvolatile memory chip adds value according to the CE selection signal to the offset value for the write-destination address contained in the write command for the first data.

17. A nonvolatile memory chip, comprising:
a data terminal configured to receive a write command for a data;
a first CE terminal configured to receive a first chip-enable signal;
a second CE terminal configured to receive a second chip-enable signal;
a CE selection terminal configured to receive a CE selection signal used to decide which the first chip-enable signal or the second chip-enable signal to be used;
a selector coupled to the first CE terminal and the second CE terminal, the selector outputting one of the first chip-enable signal and the second chip-enable signal based on the CE selection signal, wherein
an offset value for a write-destination address contained in the write command for the data is changed based on the CE selection signal, and
the write command for the data is executed using an output signal from the selector as an activate signal.

18. The nonvolatile memory chip according to claim 17, wherein
when the selector outputs the first chip-enable signal based on the CE selection signal, the offset value for the write-destination address contained in the write command for the data is set, and when the selector outputs the second chip-enable signal based on the CE selection signal, the offset value for the write-destination address contained in the write command for the data is not set.

19. The nonvolatile memory chip according to claim 17, wherein
any of digits of the offset value for the write-destination address contained in the write command for the data is switched according to the CE selection signal.

20. The nonvolatile memory chip according to claim 17, wherein
the selector outputs the first chip-enable signal when the CE selection signal is 1, and outputs the second chip-enable signal when the CE selection signal is 0; and
the CE selection signal is added to the offset value for the write-destination address contained in the write command for the data.
